(19) United States
(12) Patent Application Publication
(10) Pub. No.: US 2025/0331096 A1
(43) Pub. Date: Oct. 23, 2025

(54) HEAT SINK FOR A 3D ELECTRONIC MODULE

(71) Applicant: 3D PLUS, BUC Cedex (FR)

(72) Inventor: Pierre LE BLAY, Les Clayes-sous-Bois (FR)

(21) Appl. No.: 18/867,429

(22) PCT Filed: May 15, 2023
(86) PCT No.: PCT/EP2023/063004

§ 371 Date: Nov. 19, 2024

(30) Foreign Application Priority Data
May 25, 2022 (FR) FR2205065

(51) Int. Cl. H05K 1/02; B23P 15/26; H05K 3/30

(52) U.S. Cl. CPC H05K 1/0203; B23P 15/26; H05K 3/305; B23P 2700/10; H05K 2201/10151

(57) ABSTRACT

A heat sink component is made of a thermally conductive material and intended to thermally connect an optoelectronics sensor to a rigid cradle cooled by external cooling means; the optoelectronics sensor being mounted on a printed circuit; the cradle having at least one fixing boss and an opening intended to house the optoelectronics sensor; the heat sink component including a base intended to be placed in thermal contact with at least one fixing boss of the cradle; a protuberance intended to be placed in thermal contact with a lower face of the optoelectronics sensor through a hole passing through the printed circuit.

### CROSS-REFERENCE TO RELATED APPLICATIONS

This application is a National Stage of International patent application PCT/EP2023/063004, filed on May 15, 2023, which claims priority to foreign French patent application No. FR 2205065, filed on May 25, 2022, the disclosures of which are incorporated by reference in their entireties.

### FIELD OF THE INVENTION

The present invention relates to the field of 3-D optoelectronic modules for imaging, particularly spatial imaging. More specifically, the invention relates to the thermal management of an image sensor used in the context of space applications, whether these be scientific or industrial.

### PROBLEM ADDRESSED

In the space industry it is desirable to miniaturize optoelectronic imaging modules while using optoelectronics sensors of higher performance having greater resolution.

In the context of spatial imaging, the image sensor needs to be kept at a stable and low temperature in order to ensure that it operates correctly. The performance of an optoelectronics sensor decreases drastically when the temperature increases. The dark current increases and so black becomes gray at the time of detection. This poses problems in space applications where black is predominant in most of the images. These problems are amplified by the use of sensors of increasingly higher resolution. For the same technology of sensor, increasing the resolution leads to an increase in the electrical consumption and so the sensor dissipates more heat during its operation.

Thus, for operation under conditions of low brightness, reducing the thermal noise in the imagers is of fundamental importance. What is meant by “thermal noise” is noise generated by the thermal agitation of the charge carriers.

One problem that needs to be overcome in this context is that of keeping an optoelectronics sensor in a 3D electronic module for a space application at a low temperature. One general objective is to ensure a low operating temperature for an optoelectronics sensor so as to reduce the thermal noise and thus the dark current. That makes it possible to improve the quality of the images.

### BACKGROUND

The solutions currently employed for cooling the sensors are to add a heat exchanger of the Peltier type and a heatsink for dissipating the heat. However, this type of solution comes at a high cost. In addition, realizing and implementing this solution remain complex. This is because the surface devoted to exchange of heat in the sensor is not easily accessible for installing such a device in a 3D electronics module. Thus, implementation of a heat exchanger comes at the expense of the compactness of the 3D module.

European patent EP3340303B1 illustrates a 3D electronics module comprising an optoelectronics sensor and a thermally conductive rigid cradle in the form of a frame delimiting an opening that houses said sensor. The cradle is passively cooled and acts as a thermal mass. However, the area of contact between the cradle and the sensor is limited to the periphery of the sensor. That increases the thermal resistance between the sensor and the cradle and limits the heat-exchange area.

### Response to the Problem and Provision of a Solution

In order to alleviate the limitations of the existing solutions so far as improving the dissipation of the heat of the optoelectronics sensor incorporated into a 3D electronics module is concerned, the invention proposes a heat sink component that is inexpensive, simple to implement, and compatible with a three-dimensional structure of an electronics module. The heat sink component enables a 4° C./W reduction in the thermal resistance by comparison with the solution of European patent EP3340303B1 (3° C./W as opposed to 7° C./W). The heat sink component according to the invention makes it possible to maximize the area for exchange of heat between the sensor and the cradle whatever the way in which the sensor is held in the cradle. In addition, the invention proposes a 3D electronics module in which the heat sink component according to the invention is implemented in such a way as to create a thermal circuit connecting the sensor to an interface cooled by external means. In addition, the invention offers a method for manufacturing the 3D electronics module according to the invention.

The solution according to the invention makes it possible to improve the quality of the images in a low-brightness environment by reducing the thermal noise in the sensor. The reduction in thermal noise is achieved by reducing the thermal resistance between the sensor and the thermal mass of the module. The thermal resistance between the sensor and the thermal mass of the module is reduced by increasing the area for exchange of heat between the sensor and the thermal mass of the module.

The solution allows more effective control over the temperature of the sensor, thus making it possible to keep said sensor at a low temperature without losing out on the compactness of the 3D module.

In addition, the heat sink component according to the invention makes it possible to reduce manufacturing and assembly costs in comparison with the solutions of the prior art.

In addition, the solution according to the invention is compatible with any optical sensor having a free surface in its connections array of the LGA (Land Grid Array), BGA (Ball Grid Array), CGA (Column Grid Array) or PGA (Pin Grid Array) type.

### SUMMARY OF THE INVENTION

One subject of the invention is a heat sink component made of a thermally conductive material and intended to thermally connect an optoelectronics sensor to a rigid cradle cooled by external cooling means. The optoelectronics sensor being mounted on a printed circuit; the cradle having at least one fixing boss and an opening intended to house the optoelectronics sensor.

Said heat sink component comprising:
a base intended to be placed in thermal contact with at least one fixing boss of the cradle;
a protuberance intended to be placed in thermal contact with a lower face of the optoelectronics sensor through a hole passing through the printed circuit and passing through a hole in the printed circuit.

According to one particular aspect of the invention, the base is made up of one or more connected arms.

According to one particular aspect of the invention, the arms are coplanar in a first plane.

According to one particular aspect of the invention, the arms are connected via a common central intersection surface.

According to one particular aspect of the invention, the protuberance extends from the central intersection surface.

According to one particular aspect of the invention, the arms are connected via a mechanical fixing piece in the form of a frame or of a ring connecting the arms to one another.

According to one particular aspect of the invention, the protuberance extends from the mechanical fixing piece.

According to one particular aspect of the invention, the protuberance has a planar first upper surface.

According to one particular aspect of the invention, each arm comprises at least one end having a second upper surface intended to be bonded to the base of the associated fixing boss.

According to one particular aspect of the invention, each arm comprises at least one end of a shape that complements that of the associated lateral surface of the fixing boss.

Another subject of the invention is a 3D electronics module comprising:
an optoelectronics sensor mounted on a printed circuit,
a rigid cradle cooled by external cooling means; the cradle having a central opening intended to house the optoelectronics sensor and having at least one fixing boss,
a heat sink component according to the invention.

According to one particular aspect of the invention, the optoelectronics sensor comprises a housing in which there is housed a photosensitive chip with a planar active face, with, on the opposite face from the housing, electrical-connection pins connected to the printed circuit through the opening in the cradle.

According to one particular aspect of the invention, the height of the protuberance is chosen so as to obtain an empty-space volume between the base and the printed circuit.

According to one particular aspect of the invention, the sensor is cast in an epoxy resin.

Another subject of the invention is a manufacturing method for manufacturing a 3D electronics module according to the invention, comprising the following steps:
i—fixing the optoelectronics sensor to the cradle by bonding it to the edges of the central opening using a thermally conductive adhesive,
ii—piercing the printed circuit in order to create holes aligned with the fixing bosses of the cradle and the protuberance of the heat sink component,
iii—assembling the assembly formed by the optoelectronics sensor and the cradle with the printed circuit after inserting the fixing bosses in the dedicated holes,
iv—assembling the assembly formed by the optoelectronics sensor, the cradle and the printed circuit with the heat sink component by inserting the protuberance into the dedicated hole and by adhesively bonding the ends of the base to the support bosses using a thermally conductive adhesive.

According to one particular aspect of the invention, the method further comprises a step of casting an optoelectronics sensor in an epoxy resin after the fixing step i).

### BRIEF DESCRIPTION OF THE DRAWINGS

Other features and advantages of the present invention will become more clearly apparent on reading the following description with reference to the following appended drawings.

FIG. 1a illustrates a first perspective view of the electronics module according to a first embodiment of the invention.

FIG. 1b illustrates a second perspective view of the electronics module according to the first embodiment of the invention.

FIG. 1c illustrates a cross-sectional view of the electronics module according to the first embodiment of the invention.

FIG. 1d illustrates a perspective view of the heat sink component according to the first embodiment of the invention.

FIG. 2a illustrates a perspective view of the electronics module according to a second embodiment of the invention.

FIG. 2b illustrates a cross-sectional view of the electronics module according to the second embodiment of the invention.

FIG. 2c illustrates a perspective view of the heat sink component according to the second embodiment of the invention.

FIG. 3a illustrates a perspective view of the heat sink component according to a third embodiment of the invention.

FIG. 3b illustrates a perspective view of the heat sink component according to a fourth embodiment of the invention.

FIG. 4 illustrates a flowchart of the steps of the manufacturing method for manufacturing a 3D electronics module according to the invention.

### DETAILED DESCRIPTION

In the remainder of the description, the expressions “front”, “rear”, “upper”, “lower” are used with reference to the orientation of the figures described. Given that the elements may be positioned in other orientations, the directional terminology is indicated merely by way of illustration and is not limiting.

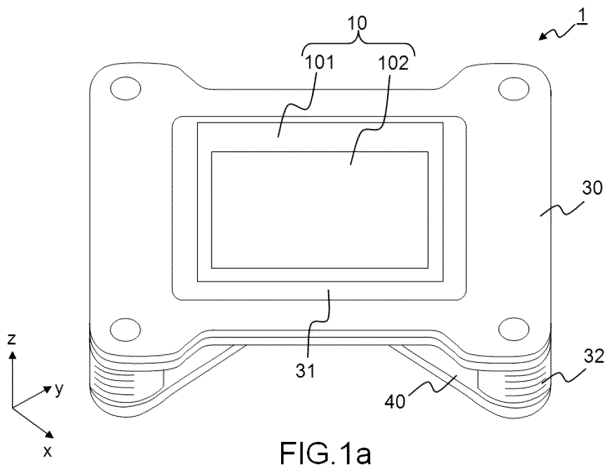

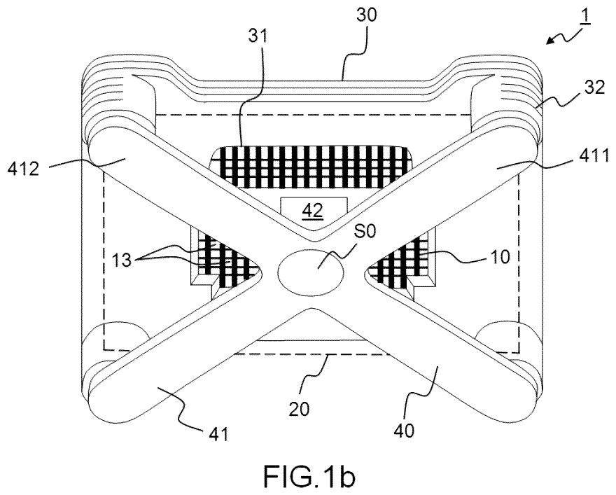

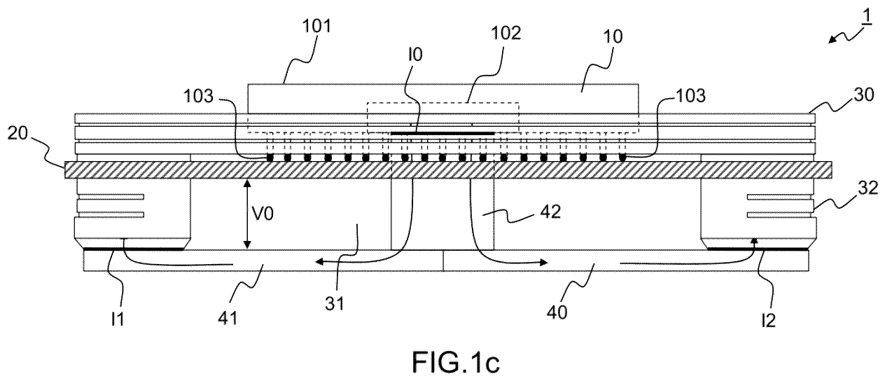

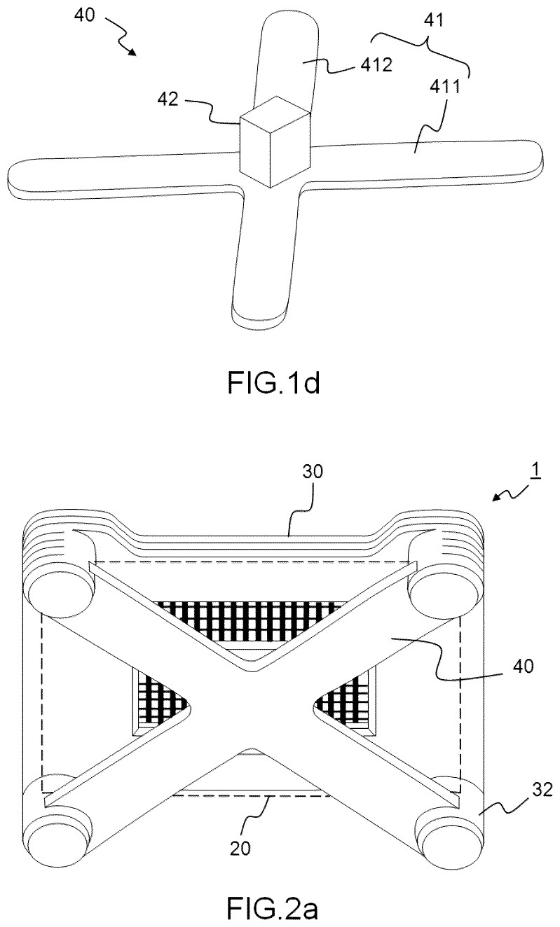

FIG. 1a illustrates a first perspective view of the electronics module 1 according to a first embodiment of the invention. The electronics module 1 comprises an optoelectronics sensor 10 mounted on a printed circuit 20, a rigid cradle 30 and a heat sink component 40. FIG. 1a illustrates the electronics module 1 from the side of the active face of the optoelectronics sensor 10. FIG. 1b illustrates a second perspective view of the electronics module according to the first embodiment of the invention. FIG. 1b illustrates the electronics module 1 from the side of the heat sink component 40.

The optoelectronics sensor 10 comprises a housing 101 in which a photosensitive chip 102 is housed. The photosensitive chip 102 has a planar active first face (orthogonal to the axis Z) able to convert photons into electrical charges. The sensor further comprises, on the opposite face orthogonal to the axis Z (in this instance the lower face) of the housing 101, electro-connection pins 103. The pins 103 are intended for connecting the photosensitive chip to the conductive tracks of the printed circuit 20. The printed circuit 20 is shown transparently in FIG. 1b so that the distribution of the pins and the lower surface of the optoelectronics sensor 10 may be seen. The pins 103 partially occupy the lower face of the housing 101 so as to leave a partial surface free of pins. In the example illustrated, this is the central surface of the lower face of the sensor 10. The pins 103 may be of the LGA (Land Grid Array), BGA (Ball Grid Array), CGA (Column Grid Array) or PGA (Pin Grid Array) type.

The printed circuit 20 may be embodied by a circuit of the PCB (Printed Circuit Board) type comprising an electrically conductive tracks. The electrically conductive tracks are connected to the pins in order to carry the signals coming from the optoelectronics sensor 10. Alternatively, it is possible to stack a plurality of printed circuits one on top of another underneath the sensor 10. The printed circuits may be interconnected by metallic vias or lateral conductive tracks.

The cradle 30 is produced in the form of a rigid frame in which the sensor 10 is positioned and bonded via its rear face comprising the pins 103. The cradle 30 performs a role of mechanically stabilizing the sensor 10. The cradle comprises an opening 31 in which the sensor 10 is housed. The periphery of the lower face of the sensor 10 rests on part of the peripheral surface of the opening 31. The opening 31 allows the pins 103 to pass toward the printed circuit 20. The opening 31 is generally rectangular, but need not necessarily be so. The sensor 10 is fixed to the cradle 30 by means of a thermally conductive adhesive at the peripheral contact surface of the opening 31. Advantageously, the sensor 10 is molded in an epoxy resin, preferably an epoxy resin filled with silica beads. That enables the sensor to be mechanically stabilized in the frame of the cradle 30.

By way of nonlimiting example, the cradle 30 is made of steel or of aluminum.

In addition, the cradle 30 has a plurality of fixing bosses 32 for mechanically stabilizing the cradle 30 and thus the 3D module 10. The printed circuit 20 has holes aligned with the positioning of the fixing bosses 32. The fixing bosses 32 are inserted into the associated holes as the printed circuit 20 is assembled with the cradle 30 by soldering. The fixing bosses 32 are inserted into the holes in the printed circuit 20 so as to obtain electrical contact between the pins 103 of the sensor and the metal tracks of the printed circuit 20, through the opening 31.

Moreover, the cradle 30 acts as a thermal mass for the entire 3D electrical module assembly 1. More specifically, it acts as a thermal interface for the sensor of the 3D electronics module. The cradle 30 is cooled by external cooling means which, for the sake of simplicity, have not been depicted. The cooling means may be achieved using various active means (heat pipe for example), or passive means (a Peltier-type device for example) connected via mechanical interfaces available on the 3D electronics module. Thus, the temperature of the cradle is kept at a target value which, in the context of the invention, is generally low.

The heat sink component 40 comprises a base 41 and a protuberance 42 which extends from the base toward the lower face of the sensor 10. The base 41 is fixed to at least one fixing boss 32 by adhesive bonding using a thermally conductive adhesive. That makes it possible to create at least one point of thermal contact between the base 41 and the cradle which acts as a thermal mass.

In addition, the protuberance 42 extends from the base until it reaches the lower face of the sensor 10, through a hole aligned with the positioning of the protuberance 42. The protuberance is inserted into the associated hole in the printed circuit 20 and its height is chosen so that it comes into abutment with the lower face of the sensor 10. That makes it possible to create at least one surface for thermal contact between the heat sink component 40 and the sensor 10 that is to be cooled. The surface for contact between the protuberance 42 and the lower face of the sensor 10 is situated in a region of said face that is free of the pins 103.

Advantageously, the protuberance 42 has a planar upper surface. It is possible to fix the upper surface of the protuberance 42 to the lower face of the sensor 10 using a thermally conductive adhesive. That makes it possible to improve the mechanical robustness of the structure of the 3D electronics module.

This results in the creation of a heat-removal circuit removing heat from the sensor 10 to the cradle 30 which acts as a thermal mass. The introduction of the heat sink component 40 makes it possible to increase the area for heat exchange between the cradle 30 and the sensor 10. Thus, the invention makes it possible to reduce the thermal resistance between the cradle and the sensor without increasing the bulk of the 3D electronics module compared with a structure that does not have such a heat-draining component.

Advantageously, the base 41 is made up of a plurality of connected arms, more particularly two coplanar arms 412 and 411 which cross one another at their middle. The first arm 411 connects a first fixing boss to the fixing boss diagonally opposite it. The second arm 412 connects a second fixing boss to the fixing boss diagonally opposite it. The second fixing boss is adjacent to the first fixing boss. Each arm has, at one end, a planar surface bearing against the lower surface of the associated fixing boss. The end of each arm is fixed to the associated fixing boss by a thermally conductive adhesive. The use of the arms makes it possible to lighten the weight of the heat sink component 40 without diminishing the mechanical robustness of the component 40. The length of each of the arms 411 and 412 is greater than or equal to the length of the diagonal of the frame of the rigid cradle 30.

The two arms 412 and 411 are connected via a central intersection surface S0 common to the two arms. The protuberance 42 extends from said intersection surface SO toward the sensor 10 mounted in the cradle.

FIG. 1c illustrates a cross-sectional view of the electronics module according to the first embodiment, so as to provide an understanding of the heat-removal path. The interface between the protuberance 42 and the lower face of the sensor 10 acts as a heat-exchange surface to receive some of the amount of heat generated by the sensor when it is in operation. The amount of heat recovered at the interface 10 is transmitted through the protuberance 42 and the arms 411 and 412 of the base 41 by thermal conduction. The thermal pathway created by the heat sink component 40 guides the heat toward the interfaces 11 and 12 between each arm of the base 41 and the associated fixing boss 31 of the cradle 30. Remember that the cradle is cooled by external cooling means. That then makes it possible to avoid the sensor 10 overheating while it is in operation by removing the heat produced through the Joule heating effect. This thus allows the sensor 10 to be kept at a target temperature and makes it possible to minimize the thermal noise in said sensor.

In the first embodiment, the base 41 of the heat sink component 40 comes to bear on the lower surfaces of the bosses 32. This makes it possible to improve the mechanical robustness of the 3D electronics module while at the same time minimizing the mechanical stress applied by the protuberance 42 to the sensor 10.

The length of the protuberance 42 is chosen so that it comes into abutment with the lower face of the sensor 10 through the printed circuit 20 and the opening 31. Advantageously, it is possible to design the length of the protuberance 42 in such a way as to obtain an empty-space volume V0 between the base 41 and the printed circuit 20. The empty space V0 can be used to house additional electronic components, so as to obtain a more compact 3D electronics module.

FIG. 1d illustrates a perspective view of just the heat sink component 40 according to the first embodiment of the invention. By way of nonlimiting example, the protuberance 42 is of parallelepipedal shape with a planar upper surface. The planar upper surface acts as a surface for the exchange of heat with the sensor. Each of the arms 411 and 412 is of a flat shape so as to improve the stability of the 3D electrical module after assembly. The flat shape at the ends of the arms enables a formal assembly in which the arms 411 and 412 rest on the fixing bosses 32 while at the same time maximizing the area available for the exchange of heat between the cradle 30 and the heat sink component 40.

The heat sink component 40 is made from thermally conductive materials such as metals (aluminum, steel, etc.), light metal alloys or thermally conductive polymers, or graphene.

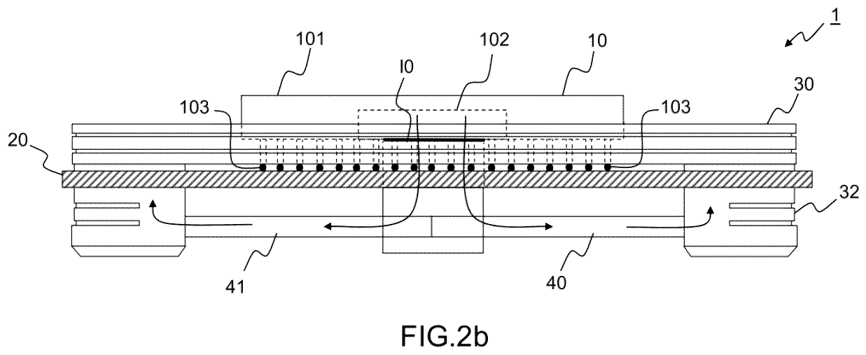

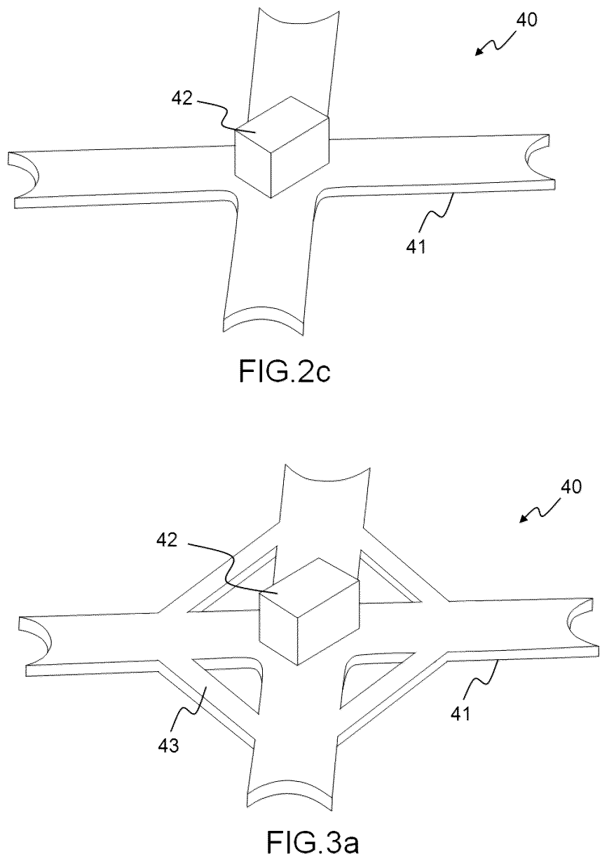

FIG. 2a illustrates a perspective view of the electronics module 1 according to a second embodiment of the invention. FIG. 2b illustrates a cross-sectional view of the electronics module according to the second embodiment of the invention. FIG. 2c illustrates a perspective view of the heat sink component according to the second embodiment of the invention.

The second embodiment of the invention reuses the same features from the first embodiment, with the exception of the shape of the ends of the arms 411 and 412 of the base 41. The end of each of the arms 411, 412 that form the base 41 of the heat sink component 40 has a shape that complements that of the associated lateral surface of the fixing boss. By way of nonlimiting example, if the fixing bosses are cylindrical in shape, the shape of the end of each of the arms is the shape of an arc of a circle, as illustrated in FIG. 2c. The heat sink component is assembled with the cradle as follows: the arc-shaped end of the arm hugs the lateral surface of the associated cylindrical fixing boss, as illustrated in FIG. 2a. This then creates a sliding connection guided by the fixing bosses 32. The heat sink component is inserted into the structure of the cradle until the top of the protuberance 42 and the lower face of the sensor 10 come into abutment with one another. A thermally conductive adhesive is applied to the upper surface of the protuberance 42 so as to mechanically fix the heat sink component 40 to the connected assembly formed by the sensor 10, the printed circuit 20 and the cradle 30.

The length of the arms 411 and 412 is equal to the length of the diagonal of the frame of the cradle so that the base 41 can be inserted as a slide guided by the fixing bosses 32.

The advantage of the second embodiment over the first is that it makes assembly easier since the heat sink component is, by construction, centered with respect to the frame of the cradle.

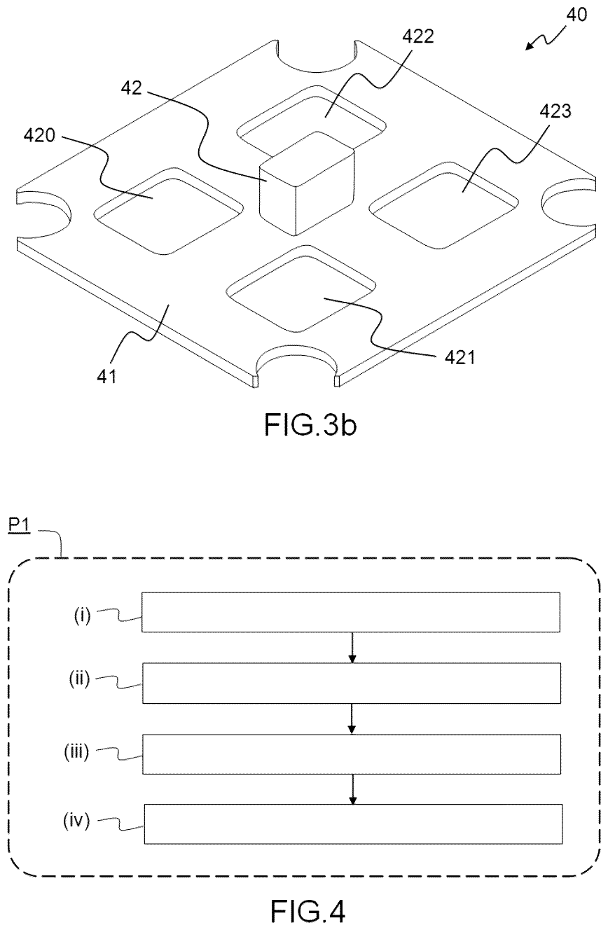

FIG. 3a illustrates a perspective view of the heat sink component 40 according to a third embodiment of the invention. According to this embodiment, the arms 411 and 412 are also connected via a mechanical fixing piece 43 in the form of a frame or of a ring connecting the arms 411, 412 to one another. That makes it possible to improve the mechanical robustness of the heat sink component. It is possible for the partial region of the lower face of the sensor 10, which partial region is aligned with the mechanical fixing piece 43, to be free of connecting pins. When that is the case, it is conceivable to create one or more protuberances which extend from the mechanical fixing piece 43 toward said partial region. Thus, the surface area for the exchange of heat is increased in comparison with the preceding embodiments.

FIG. 3b illustrates a perspective view of the heat sink component according to a fourth embodiment of the invention. In the fourth embodiment, the base is a plane comprising holes 420, 421, 422, 423 in order to lighten the weight of the component. In addition, this embodiment allows access to the components mounted in an empty-space volume V0 between the base 41 and the printed circuit 20. In addition, these holes allow the volume V0 to incorporate components of a height greater than that of the protuberance such as to extend beyond the base 41.

The advantage of the third and fourth embodiments over the previous embodiments is thus that the mechanical robustness is increased and the thermal resistance is decreased.

More generally, the shape of the base 41 is not restricted to a multi-arm structure. It is conceivable for the shape of the base to be adapted according to the shape of the frame of the cradle (rectangular, circular, etc.). By way of example, it is conceivable to produce a base 41 in the form of a solid plane parallel to the lower face of the sensor, or a planar ring (or frame) connecting the cradle boss supporting surfaces.

FIG. 4 illustrates a flowchart of the steps of the manufacturing method P1 for manufacturing an electronics module 1 according to the invention.

The first step i) is a step of fixing the optoelectronics sensor 10 to the cradle 30 by bonding it to the edges of the central opening 31 using a thermally conductive adhesive. The sensor 10 is placed in the opening 31 of the frame of the cradle 30. The periphery of the lower face of the sensor 10 rests on part of the peripheral surface of the opening 31. The sensor 10 is centered with respect to said opening 31. The sensor 10 and the cradle 30 are thus mechanically assembled.

The second step ii) is a step of piercing the printed circuit 20 in order to create holes aligned with the fixing bosses 32 of the cradle and the at least one protuberance 42 of the heat sink component 40.

Alternatively, it is conceivable to use a printed circuit 20 in which holes have already been pierced by the manufacturer.

The third step iii) is a step of assembling the assembly formed by the sensor 10 and the cradle 30 with the printed circuit 20 by inserting the fixing bosses 32 in the dedicated holes. The cradle 30 is inserted into the printed circuit 20 through the holes associated with the boxes until the pins 103 of the sensor come into contact with the metallic tracks of the printed circuit 20.

The printed circuit 20 is then assembled with the sensor 10 by soldering the pins to the metallic tracks of the printed circuit.

The fourth step iv) is a step of assembling the assembly formed by the optoelectronics sensor 10, the cradle 30 and the printed circuit 20 with the heat sink component 40. This step is performed by inserting the protuberance 42 into the dedicated hole through the printed circuit 20 until the top of the protrusion 42 and the lower face of the sensor 10 come into abutment. The ends of the base 41 are assembled with the fixing bosses 32 using a thermally conductive adhesive. It is conceivable for the thermally conductive adhesive to be applied to the upper surface of the protuberance 42 that is in contact with the lower face of the sensor 10.

Optionally, the method P1 comprises a step of casting the optoelectronics sensor 10 in an epoxy resin after the first step i), so as to strengthen the mechanical bond between the sensor and the cradle.

Optionally, the method P1 comprises a step of casting in resin the assembly formed by the sensor, the cradle, the printed circuit and the heat sink component. That then provides protection for the entire assembled structure.

1. A heat sink component made of a thermally conductive material and intended to thermally connect an optoelectronics sensor to a rigid cradle cooled by external cooling means;
the optoelectronics sensor being mounted on a printed circuit; the cradle having at least one fixing boss and an opening intended to house the optoelectronics sensor;
said heat sink component comprising:
a base intended to be placed in thermal contact with at least one fixing boss of the cradle;
a protuberance intended to be placed in thermal contact with a lower face of the optoelectronics sensor through a hole passing through the printed circuit.

2. The heat sink component as claimed in claim 1, wherein the base is made up of one or more connected arms.

3. The heat sink component as claimed in claim 2, wherein the arms are coplanar in a first plane (P1).

4. The heat sink component as claimed in claim 3, wherein the arms are connected via a common central intersection surface (S0).

5. The heat sink component as claimed in claim 4, wherein the protuberance extends from the central intersection surface.

6. The heat sink component as claimed in claim 2, wherein the arms are connected via a mechanical fixing piece in the form of a frame or of a ring connecting the arms to one another.

7. The heat sink component as claimed in claim 6, wherein the protuberance extends from the mechanical fixing piece.

8. The heat sink component as claimed in claim 1, wherein the protuberance has a planar first upper surface.

9. The heat sink component as claimed in claim 2, wherein each arm comprises at least one end having a second upper surface intended to be bonded to the base of the associated fixing boss.

10. The heat sink component as claimed in claim 2, wherein each arm comprises at least one end of a shape that complements that of the associated lateral surface of the fixing boss.

11. A 3D electronics module comprising:
an optoelectronics sensor mounted on a printed circuit
a rigid cradle cooled by external cooling means; the cradle having a central opening intended to house the optoelectronics sensor and having at least one fixing boss,
a heat sink component as claimed in claim 1.

12. The 3D electronics module as claimed in claim 11, wherein the optoelectronics sensor comprises a housing wherein there is housed a photosensitive chip with a planar active face, with, on the opposite face from the housing, electrical-connection pins connected to the printed circuit through the opening.

13. The 3D electronics module as claimed in claim 11, wherein the height of the protuberance is chosen so as to obtain an empty-space volume (V0) between the base and the printed circuit.

14. The 3D electronics module as claimed in claim 11, wherein the sensor is cast in an epoxy resin.

15. A manufacturing method for manufacturing a 3D electronics module as claimed in claim 11, comprising the following steps:
i—fixing the optoelectronics sensor to the cradle by bonding it to the edges of the central opening using a thermally conductive adhesive,
ii—piercing the printed circuit in order to create holes aligned with the fixing bosses of the cradle and the protuberance of the heat sink component,
iii—assembling the assembly formed by the optoelectronics sensor and the cradle with the printed circuit after inserting the fixing bosses in the dedicated holes,
iv—assembling the assembly formed by the optoelectronics sensor, the cradle and the printed circuit with the heat sink component by inserting the protuberance into the dedicated hole and by adhesively bonding the ends of the base to the support bosses using a thermally conductive adhesive.

16. The manufacturing method (P1) as claimed in claim 15, wherein the sensor is cast in an epoxy resin, and further comprising a step of casting an optoelectronics sensor in an epoxy resin after the fixing step i).
